(19) United States
(12) Patent Application Publication
(10) Pub. No.: US 2026/0206378 A1
(43) Pub. Date: Jul. 16, 2026

(54) LIGHT EMITTING APPARATUS

(71) Applicant: SEOUL VIOSYS CO., LTD., Ansan-si (KR)

(72) Inventors: KiYon PARK, Ansan-si (KR); JaeHak JEONG, Ansan-si (KR)

(21) Appl. No.: 19/406,451

(22) Filed: Dec. 2, 2025

Related U.S. Application Data
(60) Provisional application No. 63/728,906, filed on Dec. 6, 2024.

(51) Int. Cl. H10H 20/853; H10H 20/856

(52) U.S. Cl. CPC H10H 20/853; H10H 20/856

(57) ABSTRACT

A light emitting apparatus includes: a substrate; a light emitting device mounted on the substrate to generate light; a sidewall extending upward from the substrate and configured to reflect the light of the light emitting device; and a light transmissive layer having an edge supported on an upper side of the sidewall and configured to transmit light from the light emitting device, in which the light emitting device is disposed inside the sidewall, and the edge of the light transmissive layer is located closer to an outer surface of the sidewall than an inner surface of the sidewall.

### CROSS REFERENCE TO RELATED APPLICATION

This application claims priority from and the benefit of U.S. Provisional Patent Application No. 63/728,906, filed Dec. 6, 2024, which is hereby incorporated by reference for all purposes as if fully set forth herein.

### BACKGROUND

### Field

Embodiments of the invention relate generally to a light emitting apparatus.

### Discussion of the Background

A light emitting apparatus is a semiconductor device emitting light generated by the recombination of electrons and holes, and is recently used in various fields such as sterilization and insect trapping, in addition to displays, automobile lamps, and general lighting. Light emitting diodes are applied to various fields such as automobile lamps and display apparatuses because they have a long lifespan, low power consumption, and a fast response speed.

Recently, as the uniformity of light emitting apparatuses has been emphasized, the need for a light emitting element for irradiating similar light over a wide area has been increasing.

The above information disclosed in this Background section is only for understanding of the background of the inventive concepts, and, therefore, it may contain information that does not constitute prior art.

### SUMMARY

Embodiments of the present disclosure provide a light emitting apparatus for efficiently emitting light by efficiently reflecting light.

Embodiments of the present disclosure provide a light emitting apparatus for efficiently emitting light by increasing the light extraction efficiency of the light emitting apparatus.

Embodiments of the present disclosure provide a light emitting apparatus for irradiating uniform light over a wide area.

Embodiments of the present disclosure provide a light emitting apparatus reducing damage caused by external impact by increasing the structural stability of the apparatus.

Additional features of the inventive concepts will be set forth in the description which follows, and in part will be apparent from the description, or may be learned by practice of the inventive concepts.

According to an embodiment of the present disclosure, a light emitting apparatus includes: a substrate; a light emitting device mounted on the substrate and configured to generate light; a sidewall extending upward from the substrate and configured to reflect the light of the light emitting device; and a light transmissive layer having an edge mounted on an upper side of the sidewall and configured to transmit light from the light emitting device, in which the light emitting device is disposed inside the sidewall, and the edge of the light transmissive layer is located closer to an outer surface of the sidewall than an inner surface of the sidewall.

The light emitting apparatus may further include a molding layer covering the light emitting device and located inside the sidewall, in which the light transmissive layer may be disposed on an upper side of the molding layer.

The molding layer and the light transmissive layer may be integrally formed.

A surface of the light transmissive layer may be formed to be convex upward.

A height of the sidewall may be less than a height of the light transmissive layer.

In another embodiment of the present disclosure, a light emitting apparatus includes: a substrate; a light emitting device mounted on the substrate and configured to generate light; a sidewall extending upward from the substrate and configured to reflect the light of the light emitting device; and a light transmissive layer having an edge mounted on an upper side of the sidewall and configured to transmit light from the light emitting device, wherein the light emitting device is disposed inside the sidewall, in which the sidewall includes: a first sidewall disposed to face one side of the light emitting device; and a second sidewall disposed to face another side of the light emitting device opposite the one side, and a beam angle of the light emitting device is less than an angle formed by a first virtual line connecting one side of the top of the light emitting device and a top of the first sidewall, and a second virtual line connecting another side, opposite to the one side, of the top of the light emitting device and a top of the second sidewall.

An inner surface of each of the first sidewall and the second sidewall may include: a first reflective surface extending downward from an upper surface; a second reflective surface extending downward from a lower side of the first reflective surface, and disposed to be inclined at a predetermined angle with respect to the substrate to approach the light emitting device as the second reflective surface extends downward; and a third reflective surface extending from a lower side of the second reflective surface to the substrate.

The third reflective surface may be disposed to be inclined at a predetermined angle with respect to the substrate so as to be closer to the light emitting device toward a lower side, and an angle between the third reflective surface and the substrate may be different from an angle between the second reflective surface and the substrate.

The angle between the third reflective surface and the substrate may be greater than the angle between the second reflective surface and the substrate.

A length of the first reflective surface in a vertical direction and a length of the third reflective surface in a vertical direction may be different from each other.

An angle formed by a third virtual line connecting one side of the top of the light emitting device and a lower side of the second reflective surface of the first sidewall, and a fourth virtual line connecting another side of the top of the light emitting device and a lower side of the second reflective surface of the second sidewall, may exceed 180°.

An angle formed by a fifth virtual line connecting one side of the top of the light emitting device and an upper side of the second reflective surface of the first sidewall, and a sixth virtual line connecting the other side of the top of the light emitting device and an upper side of the second reflective surface of the second sidewall, may be less than 180°.

A length of the second reflective surface in a vertical direction may be longer than a length of each of the first reflective surface and the third reflective surface in the vertical direction.

A height of the top of the light emitting device may be higher than a height of a lower side of the second reflective surface and lower than a height of an upper side of the second reflective surface.

A length of the second reflective surface in a horizontal direction may be longer than a length of the top of the first sidewall and a length of the top of the second sidewall in the horizontal direction.

A length of the second reflective surface in a horizontal direction may be longer than a length of the light emitting device in the horizontal direction.

According to another embodiment of the present disclosure, a light emitting apparatus includes: a substrate; a light emitting device mounted on the substrate and configured to generate light; a sidewall extending upward from the substrate; and a light transmissive layer having an edge mounted on an upper side of the sidewall to transmit light from the light emitting device, in which a center of a surface of the light transmissive layer is shaped to be convex upward, and an edge of the surface of the light transmissive layer is shaped to be concave downward.

A curvature of the center of the surface of the light transmissive layer and a curvature of the edge of the surface of the light transmissive layer may be different from each other.

A center of curvature of the center of the surface of the light transmissive layer may be located lower than the light transmissive layer.

A center of curvature of the edge of the surface of the light transmissive layer may be disposed above the light transmissive layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic diagram illustrating a light emitting apparatus according to an embodiment of the present disclosure.

FIG. 2 is a schematic cross-sectional view of the light emitting apparatus of FIG. 1, taken along the line A-A′.

FIG. 3 is an enlarged schematic view of portion A of the light emitting apparatus of FIG. 1.

FIG. 4 is a graph schematic showing a beam angle of a light emitting element of the light emitting apparatus of FIG. 1.

FIG. 5 is a diagram schematic illustrating a light emitting apparatus according to a second embodiment of the present disclosure.

FIG. 6 is an enlarged schematic view of portion B of the light emitting apparatus of FIG. 2.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z—axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus 1 according to an embodiment of the present disclosure will be described.

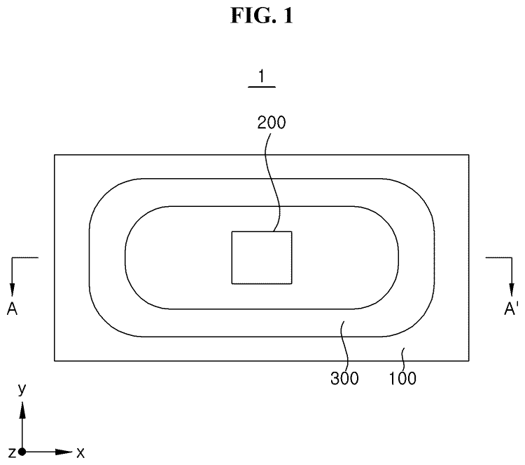

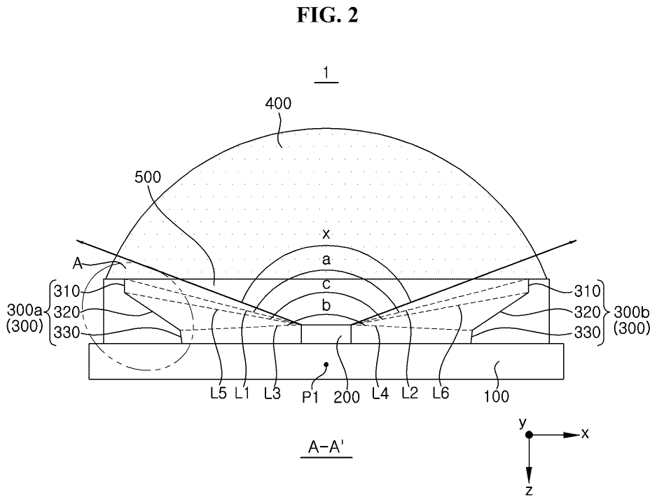

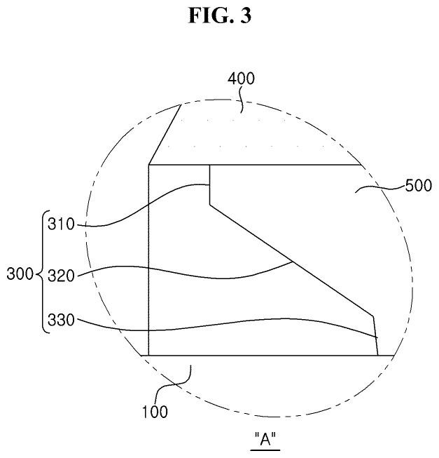

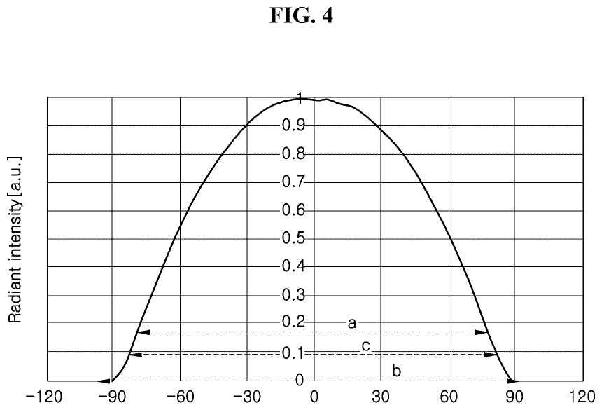

Referring to FIGS. 1, 2, 3, and 4, the light emitting apparatus 1 may generate light by receiving power from an external source. One or more light emitting apparatuses 1 may incorporated into various products, including a lighting fixture, a display apparatus, an insect trap, and similar applications. In lighting applications, the apparatus may be implemented in vehicular lighting systems such as a taillight, a headlight, a rear lamp, a tail lamp, and the like. Furthermore, when the light emitting apparatus 1 is applied to a display apparatus, a display apparatus with improved luminance having a uniform brightness in a display area may be implemented. The light emitting apparatus 1 may include a substrate 100, a light emitting device 200, a sidewall 300, a light transmissive layer 400, and a molding layer 500.

The substrate 100 may support the light emitting device 200, the sidewall 300, the light transmissive layer 400, and the molding layer 500. For example, the substrate 100 may be a lead frame. Furthermore, the substrate 100 may include one or more of Cu, Zn, Au, Ni, Al, Mg, Cd, Be, W, Mo, Si, Ag, and Fe having electrical conductivity, or an alloy including some of them. However, this may be merely an example, and the substrate 100 may be a printed circuit board (PCB) and may include one or more of FR-1, CEM-1, and FR-4. Here, FR-1 may be a material in which copper foil and laminate paper are laminated, and CEM-1 is a material in which copper foil, glass fiber fabric, laminate paper, and glass fiber fabric are sequentially laminated. Furthermore, FR-4 may be a material in which copper foil and glass fiber fabric or glass fiber fabric are laminated. Furthermore, the substrate 100 may include ceramics such as alumina (Al₂O₃), aluminum nitride (AlN), ZTA (Zirconia Toughened Alumina), and the like.

The light emitting device 200 may be mounted on the substrate 100 and configured to generate light. The light emitting device 200 may be electrically connected to an electrical circuit of the substrate 100 and and may emit light by receiving electrical power from an external source through the electrical circuit. For example, the light emitting device 200 may be any device capable of converting electrical energy into light, such as a light emitting diode (LED), a laser diode, or an organic light emitting diode (OLED). The light-emitting device 200 may be configured to emit various wavelengths, including UVC (about 200 nm to about 280 nm), UVB (about 280 nm to about 315 nm), UVA (about 315 nm to about 420 nm), blue light, green light, yellow light, red light, infrared light, and the like. Furthermore, the light emitting device 200 may be implemented in the form of a flip chip, a lateral chip, or a vertical chip.

The sidewall 300 may be mounted on one surface of the substrate 100. The sidewall 300 may be made of a polymer compound such as Epoxy Resins, PPA (Polyphthalamide), PMMA (Polymethyl Methacrylate), LCP (Liquid Crystal Polymer), PC (Polycarbonate), PBT, PET, or silicone. Furthermore, reflective particles such as TiO, Al₂O₃, or BaSO₄ may be included to increase reflectivity. Furthermore, the sidewall 300 may also be made of aluminum, copper, ceramic, stainless steel, etc. with high heat resistance. Furthermore, a metal coating such as Ag, Ni, Au, Al, etc. may be applied to the surface to increase reflectivity. Through this, a light path may be controlled (adjusted), and a design difficulty of the sidewall 300 may be reduced.

The light emitting device 200 may be disposed within the sidewall 300. The sidewall 300 may serve to reflect the light emitted from the light emitting device 200 in an upward direction. A height of the sidewall 300 may be greater than a height of the light emitting device 200. Through this, a beam angle may be adjusted by controlling a path of light emitted from the light emitting device 200. The sidewall 300 may include a first sidewall 300a and a second sidewall 300b arranged around the light emitting device 200.

The first sidewall 300a may be disposed to face one side of the light emitting device 200 and may be spaced apart from the one side of the light emitting device 200 by a predetermined distance.

The second sidewall 300b may be disposed to face another side of the light emitting device 200 opposite the one side, and may be spaced apart from the other side of the light emitting device 200 by a predetermined distance. The light emitting device 200 may be disposed between the first sidewall 300a and the second sidewall 300b.

A first angle (a), defined between a first virtual line L1 connecting a top of the first sidewall 300a and one side of a top of the light emitting device 200, and a second virtual line L2 connecting a top of the second sidewall 300b to the opposite side of the top surface of the light emitting device 200, may be formed to be greater than a beam angle (x) of the light emitting device 200.

For example, when the beam angle of the light emitting device 200 is about 120°, the first angle (a) may be about 130° or greater. More specifically, the first angle (a) may be about 160° or greater. At this first angle (α), the normalized radiant intensity of the chip at the first angle (a) may be less than about 20%. Through this configuration, light loss caused by the sidewall 300 may be reduced.

The beam angle (x) of the light emitting device 200 may be measured using a goniophotometer. To measure the beam angle (x) of the light emitting device 200, the light emitting device 200 may be mounted on a PCB or a planar substrate. The beam angle of the light emitting apparatus 1 may also be measured using the goniophotometer. The beam angle (x) of the light emitting device 200 or the light emitting apparatus 1 may be measured in a state of being spaced apart by a distance of about 1 m from the light emitting device 200, with the front of the light emitting device 200 oriented forward. Furthermore, the beam angle (x) may be defined as the angle between a point where the luminous intensity is about 50% of the maximum luminous intensity between about −90° and a reference line about 0°, and a point where the luminous intensity is about 50% of the maximum luminous intensity between the reference line about 0° and about +90°, measured by rotating from about −90° to about +90° with respect to a virtual reference line perpendicular to the light emitting surface of the light emitting device 200 and measuring the luminous intensity at each angle.

Furthermore, an inner surface of each of the first sidewall 300a and the second sidewall 300b may include a first reflective surface 310, a second reflective surface 320, and a third reflective surface 330.

The first reflective surface 310 may extend downward from an upper portion of each of the first sidewall 300a and the second sidewall 300b. A length of the first reflective surface 310 in a vertical direction may be smaller than a length of the second reflective surface 320 in the vertical direction. Due to the first reflective surface 310, light loss by the first reflective surface 310 may be reduced. Since a length of the first reflective surface 310 in the vertical direction and a length of the third reflective surface 330 in the vertical direction may be formed to be different from each other, design complexity during the manufacturing process may be reduced. A length of the first reflective surface 310 in an extending direction may be formed to be smaller than a length (width) of the light emitting device 200 in a horizontal direction (x-axis direction) perpendicular to the reference line. Furthermore, since the length of the first reflective surface 310 in the extending direction may be formed to be smaller than a length (height) of the light emitting device 200 in the extending direction, light loss may be reduced. The first reflective surface 310 may be inclined at about 80° or more and less than about 90° with respect to a horizontal plane of the substrate 100, so light may be reflected upward from the first reflective surface 310 and light extraction efficiency may be increased.

Meanwhile, the first virtual line L1 may be a virtual line connecting an upper side of the first reflective surface 310 of the first sidewall 300a and one side of the top of the light emitting device 200. Furthermore, the second virtual line L2 may be a virtual line connecting an upper side of the first reflective surface 310 of the second sidewall 300b and the other side of the top of the light emitting device 200.

The second reflective surface 320 may extend downward from an upper side of the first reflective surface 310 and may be disposed to be inclined at a predetermined angle with respect to the substrate 100 so as to approach the light emitting device 200 toward its lower side. In other words, a separation distance in a horizontal direction between an upper side of the second reflective surface 320 and the light emitting device 200 may be greater than a separation distance in the horizontal direction between a lower side of the second reflective surface 320 and the light emitting device 200. Furthermore, the second reflective surface 320 may be inclined at an angle in the range from about 30° to about 45° with respect to the horizontal plane of the substrate 100. The second reflective surface 320 may reflect light reflected to a side of the light emitting device 200 in an upward direction. Since a height of the light emitting device 200 may be located below a height of the upper side of the second reflective surface 320 and higher than a height of the lower side of the second reflective surface 320, light directed to an outside of the beam angle (x) of the light emitting device 200 may be reflected upward.

A length of the second reflective surface 320 in the horizontal direction (x-axis direction) may be longer than a length of the light emitting device 200 in the horizontal direction (x-axis direction), a length of the top of the first sidewall 300a in the horizontal direction (x-axis direction), and a length of the top of the second sidewall 300b in the horizontal direction (x-axis direction). Since an extension length of the second reflective surface 320 may be longer than an extension length of the first reflective surface 310 and an extension length of the third reflective surface 330, a reflection area may be secured and the beam angle may increase. Furthermore, a vertical length of the second reflective surface 320 may be longer than a vertical length of the first reflective surface 310 and a vertical length of the third reflective surface 330. The first reflective surface 310, the second reflective surface 320, and the third reflective surface 330 may reflect light reflected toward the interior of the light emitting apparatus 1 upward, thereby increasing light extraction efficiency.

A second angle (b) between a third virtual line L3 connecting a lower side of the second reflective surface 320 of the first sidewall 300a and one side of the top of the light emitting device 200, and a fourth virtual line L4 connecting a lower side of the second reflective surface 320 of the second sidewall 300b and the other side of the top of the light emitting device, may be formed to be larger than the first angle (a) and the beam angle (x). In other words, the second angle (b) may exceed 180°. For example, the second angle (b) may be about 185°. At the second angle (b), a normalized radiant intensity of the light emitting device 200 may be less than about 1%. Due to the second angle (b), light absorption at the third reflective surface 330 may be reduced, thereby increasing light extraction efficiency.

Furthermore, a third angle (c) between a fifth virtual line L5 connecting an upper side of the second reflective surface 320 of the first sidewall 300a and one side of the top of the light emitting device 200, and a sixth virtual line L6 connecting an upper side of the second reflective surface 320 of the second sidewall 300b and the other side of the top of the light emitting device 200, may be larger than the first angle (a) and smaller than the second angle (b). Furthermore, the third angle (c) may be less than about 180°. Since a normalized radiant intensity of the light emitting device 200 between the third angle (c) and the second angle (b) may be less than about 10%, light absorption at the second reflective surface 320 is reduced, upward reflection of light may be enhanced, light extraction efficiency is increased, and a desired light beam angle may be achieved.

The third reflective surface 330 may extend downward from the second reflective surface 320. Furthermore, the third reflective surface 330 may be disposed to be inclined at a predetermined angle with respect to the substrate 100 so that the third reflective surface 330 becomes closer to the light emitting device 200 as it extends downward from the second reflective surface 320. In other words, a separation distance in a horizontal direction between an upper side of the third reflective surface 330 and the light emitting device 200 may be greater than a separation distance in the horizontal direction between a lower portion of the third reflective surface 330 and the light emitting device 200. Due to the configuration of third reflective surface 330, a predetermined normalized radiant intensity of the side of the light emitting device 200 may be reflected in an upward direction, thereby increasing light extraction efficiency. Furthermore, an angle between the third reflective surface 330 and the substrate 100 may differ from an angle between the second reflective surface 320 and the substrate 100. The angle between the third reflective surface 330 and the substrate 100 may be greater than the angle between the second reflective surface 320 and the substrate 100. The second reflective surface 320 may enhance light extraction efficiency by reflecting light in an upward direction, while the third reflective surface 330 may reduce asymmetry of the beam angle of the light emitting device 200 by reflecting light in an upward direction opposite to a traveling direction.

Furthermore, the length of the third reflective surface 330 in the vertical direction may be different from the length of the first reflective surface 310 in the vertical direction. Furthermore, an angle between the third reflective surface 330 and the horizontal plane of the substrate 100 may be greater than an angle between the first reflective surface 310 and the horizontal plane of the substrate 100. The third reflective surface 330 may reduce asymmetry of the beam angle by reflecting light that is directed downward from an upper portion of the light emitting device 200 in a direction opposite to the traveling direction.

The light transmissive layer 400 may be disposed on one surface of the molding layer 500 and the sidewall 300 to allow light to pass through. The light transmissive layer 400 may refract the light generated from the light emitting device 200. In other words, the light transmissive layer 400 may refract the emitted light so that the beam angle of the light emitting apparatus 1 increases.

An edge of the light transmissive layer 400 may be disposed on an upper side of the sidewall 300. Furthermore, the edge of the light transmissive layer 400 may be supported on the upper side of the sidewall 300 such that the edge is located closer to an outer surface of each sidewall 300 than an inner surface of each sidewall 300. When the edge of the light transmissive layer 400 is disposed closer to the outer surface of the sidewall 300, a width of the light transmissive layer 400 may be formed to be larger than when the edge of the light transmissive layer 400 is disposed closer to the inner surface of the sidewall 300. That is, a maximum width of the light transmissive layer 400 may be greater than a maximum width of the inner surface of the sidewall 300. Furthermore, since the width of the light transmissive layer 400 may be formed to be large, light passing through the light transmissive layer 400 may be refracted more largely in the horizontal direction. In other words, since the width of the light transmissive layer 400 may be formed to be large, the beam angle of the light emitting apparatus 1 may be formed to be larger.

Furthermore, a length of the light transmissive layer 400 in the vertical direction may be formed to be greater than a length of the sidewall 300 in the vertical direction. Furthermore, the light transmissive layer 400 may be formed to be convex upward. A center of curvature P1 of a surface of the light transmissive layer 400 may be disposed below a bottom surface of the light transmissive layer 400. In an example, the center of curvature P1 of the surface of the light transmissive layer 400 may be located within a region among the molding layer 500, the substrate 100, and the light emitting device 200. By configuring the center of curvature P1 of the surface of the light transmissive layer 400 in this manner, the beam angle of the light emitting apparatus 1 may be greater than the beam angle of the light emitting device 200. In a second example, the center of curvature P1 of the surface of the light transmissive layer 400 may be disposed below the substrate 100. Due to the light transmissive layer 400, the beam angle of the light emitting apparatus 1 may be formed to be greater than the beam angle of the light emitting apparatus 1 in the example described above. In other words, the beam angle of the light emitting device 200 when the center of curvature P1 of the surface of the light transmissive layer 400 is disposed below the substrate 100 may be formed to be larger than the beam angle of the light emitting device 200 when the center of curvature P1 of the surface of the light transmissive layer 400 is disposed in a region among the molding layer 500, the substrate 100, and the light emitting device 200.

The molding layer 500 may be disposed on one surface of the substrate 100 to cover the light emitting device 200. Light generated from the light-emitting device 200 may sequentially pass through the molding layer 500 and the light transmissive layer 400. The combination of the molding layer 500 and the light-transmissive layer 400 may reduce design difficulty by adjusting the beam angle. Furthermore, the molding layer 500 may be disposed between the sidewalls 300 and below the light transmissive layer 400. Furthermore, the molding layer 500 may be integrally formed with the light transmissive layer 400. When the molding layer 500 and the light transmissive layer 400 are integrally formed, the number of interfaces may be reduced, thereby improving the reliability of the light-emitting apparatus 1.

Hereinafter, an operation and effect of the light emitting apparatus 1 according to an embodiment of the present disclosure will be described.

Light generated from the light emitting device 200 of the light emitting apparatus 1 of the present disclosure may be refracted while sequentially passing through the molding layer 500 and the light transmissive layer 400. A portion of the light generated from the light emitting device 200 may pass through the light transmissive layer 400 after being reflected upward from the sidewall 300.

This light emitting apparatus 1 has an effect that a surface emission effect may be improved because it can efficiently reflect light.

Furthermore, light can be efficiently emitted by increasing the light extraction efficiency of the light emitting apparatus 1.

Furthermore, the light emitting apparatus 1 may efficiently emit light because the light extraction efficiency is improved and the beam angle can increase through the use of differences in refractive indices.

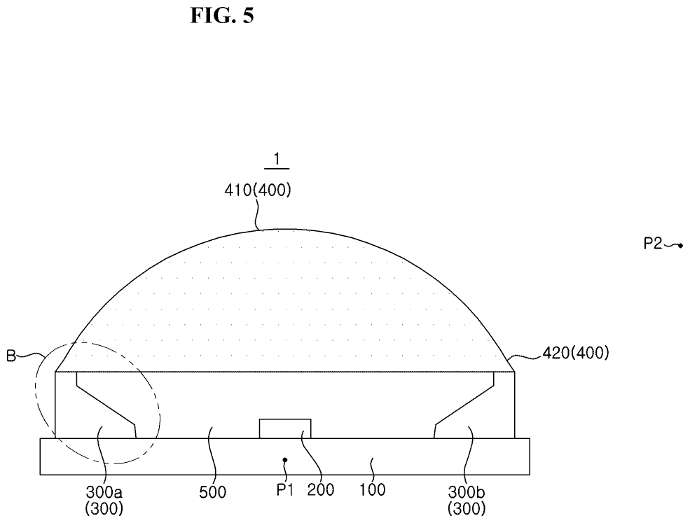

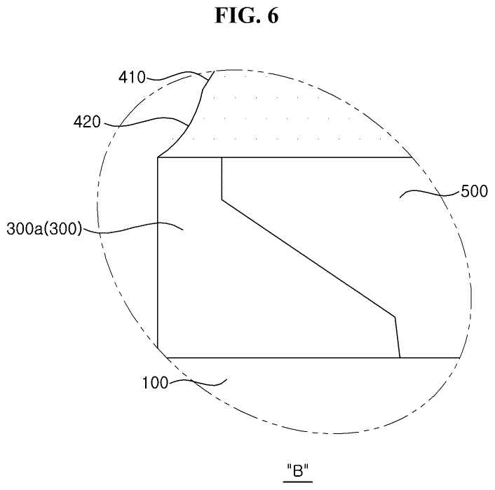

Hereinafter, a light emitting apparatus 1 according to a second embodiment of the present disclosure will be described with reference to FIGS. 5 and 6. In describing another embodiment, there is a difference in that an edge of a surface of the light transmissive layer 400 is concavely formed downward, and this difference will be mainly described.

A center of the surface of the light transmissive layer 400 may be formed as a convex surface 410 that is convexly formed upward. The convex surface 410 may have a first center of curvature P1. Furthermore, the edge of the surface of the light transmissive layer 400 may be formed as a concave surface 420 that is concavely shaped downward. The concave surface 420 may have a second center of curvature P2. The concave surface 420 may increase light extraction efficiency by refracting light that is totally reflected from the sidewall 300 toward an upper portion direction back to the outside.

A curvature of this convex surface 410 and a curvature of the concave surface 420 may be formed to be different from each other. The first center of curvature P1 of the convex surface 410 may be located below the light transmissive layer 400. The first center of curvature P1 of the convex surface 410 may correspond to the same as the center of curvature P1 described in the embodiment above. A second center of curvature P2 of the concave surface 420 may be disposed outside the light transmissive layer 400. For example, the second center of curvature P2 of the concave surface 420 may be located above the light transmissive layer 400. Since light directed toward the concave surface 420 may be reflected upward, light extraction efficiency may be increased. Furthermore, a separation distance in a horizontal direction between the second center of curvature P2 of the concave surface 420 and the light emitting device 200 may be formed to be greater than a separation distance in a horizontal direction between the light emitting device 200 and the sidewall 300.

Hereinafter, an operation and effect of the light emitting apparatus 1 according to another embodiment of the present disclosure will be described.

A certain portion of the light generated from the light emitting device 200 of the light emitting apparatus 1 according to another embodiment may be refracted while passing through the convex surface 410. Furthermore, another portion of the light generated from the light emitting device 200 may be refracted while passing through the concave surface 420. For example, light generated from the light emitting device 200 may pass through the concave surface 420 after being reflected from the sidewall 300. Light transmitted through the concave surface 420 may be refracted more than light transmitted through the convex surface 410.

Since light passing through the concave surface 420 may be refracted more than light passing through the convex surface 410, the beam angle of the light emitting apparatus 1 may become larger.

According to embodiments of the present disclosure, a surface emission effect may be improved because the light emitting apparatus may efficiently reflect light.

Furthermore, according to embodiments of the present disclosure, light may be efficiently emitted by increasing the light extraction efficiency of the light emitting apparatus.

Furthermore, according to embodiments of the present disclosure, light may be efficiently emitted by improving light extraction efficiency by using a difference in refractive indices.

Furthermore, according to embodiments of the present disclosure, a beam angle may be increased.

Furthermore, according to embodiments of the present disclosure, damage caused by external impact may be reduced by increasing the structural stability of the apparatus.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

1. A light emitting apparatus comprising:
a substrate;
a light emitting device mounted on the substrate and configured to generate light;
a sidewall extending upward from the substrate and configured to reflect the light of the light emitting device; and
a light transmissive layer having an edge mounted on an upper side of the sidewall and configured to transmit light from the light emitting device,
wherein the light emitting device is disposed inside the sidewall, and
wherein the edge of the light transmissive layer is located closer to an outer surface of the sidewall than an inner surface of the sidewall.

2. The light emitting apparatus of claim 1, further comprising a molding layer covering the light emitting device and located inside the sidewall,
wherein the light transmissive layer is disposed on an upper side of the molding layer.

3. The light emitting apparatus of claim 2, wherein the molding layer and the light transmissive layer are integrally formed.

4. The light emitting apparatus of claim 1, wherein a surface of the light transmissive layer is formed to be convex upward.

5. The light emitting apparatus of claim 1, wherein a height of the sidewall is less than a height of the light transmissive layer.

6. A light emitting apparatus comprising:
a substrate;
a light emitting device mounted on the substrate and configured to generate light;
a sidewall extending upward from the substrate and configured to reflect the light of the light emitting device; and
a light transmissive layer having an edge mounted on an upper side of the sidewall and configured to transmit light from the light emitting device,
wherein the light emitting device is disposed inside the sidewall,
wherein the sidewall includes:
a first sidewall disposed to face one side of the light emitting device; and
a second sidewall disposed to face another side of the light emitting device opposite the one side, and
wherein a beam angle of the light emitting device is less than an angle formed by a first virtual line connecting one side of a top of the light emitting device and a top of the first sidewall, and a second virtual line connecting another side, opposite to the one side, of the top of the light emitting device and a top of the second sidewall.

7. The light emitting apparatus of claim 6, wherein an inner surface of each of the first sidewall and the second sidewall includes:
a first reflective surface extending downward from an upper surface;
a second reflective surface extending downward from a lower side of the first reflective surface, and disposed to be inclined at a predetermined angle with respect to the substrate to approach the light emitting device as the second reflective surface extends downward; and
a third reflective surface extending from a lower side of the second reflective surface to the substrate.

8. The light emitting apparatus of claim 7, wherein the third reflective surface is disposed to be inclined at a predetermined angle with respect to the substrate so as to be closer to the light emitting device toward a lower side, and
wherein an angle between the third reflective surface and the substrate is different from an angle between the second reflective surface and the substrate.

9. The light emitting apparatus of claim 8, wherein the angle between the third reflective surface and the substrate is greater than the angle between the second reflective surface and the substrate.

10. The light emitting apparatus of claim 7, wherein a length of the first reflective surface in a vertical direction and a length of the third reflective surface in a vertical direction are different from each other.

11. The light emitting apparatus of claim 7, wherein an angle formed by a third virtual line connecting one side of the top of the light emitting device and a lower side of the second reflective surface of the first sidewall, and a fourth virtual line connecting another side of the top of the light emitting device and a lower side of the second reflective surface of the second sidewall, exceeds 180°.

12. The light emitting apparatus of claim 7, wherein an angle formed by a fifth virtual line connecting one side of the top of the light emitting device and an upper side of the second reflective surface of the first sidewall, and a sixth virtual line connecting the other side of the top of the light emitting device and an upper side of the second reflective surface of the second sidewall, is less than 180°.

13. The light emitting apparatus of claim 7, wherein a length of the second reflective surface in a vertical direction is longer than a length of each of the first reflective surface and the third reflective surface in the vertical direction.

14. The light emitting apparatus of claim 7, wherein a height of the top of the light emitting device is greater than a height of a lower side of the second reflective surface and lower than a height of an upper side of the second reflective surface.

15. The light emitting apparatus of claim 7, wherein a length of the second reflective surface in a horizontal direction is longer than a length of the top of the first sidewall and a length of the top of the second sidewall in the horizontal direction.

16. The light emitting apparatus of claim 7, wherein a length of the second reflective surface in a horizontal direction is longer than a length of the light emitting device in the horizontal direction.

17. A light emitting apparatus comprising:
a substrate;
a light emitting device mounted on the substrate and configured to generate light;
a sidewall extending upward from the substrate; and
a light transmissive layer having an edge mounted on an upper side of the sidewall and configured to transmit light from the light emitting device,
wherein a center of a surface of the light transmissive layer is shaped to be convex upward, and
wherein an edge of the surface of the light transmissive layer is shaped to be concave downward.

18. The light emitting apparatus of claim 17, wherein a curvature of the center of the surface of the light transmissive layer and a curvature of the edge of the surface of the light transmissive layer are different from each other.

19. The light emitting apparatus of claim 17, wherein a center of curvature of the center of the surface of the light transmissive layer is located lower than the light transmissive layer.

20. The light emitting apparatus of claim 17, wherein a center of curvature of the edge of the surface of the light transmissive layer is disposed above the light transmissive layer.
